(19) United States
(12) Patent Application Publication
(10) Pub. No.: US 2006/0286734 A1
(43) Pub. Date: Dec. 21, 2006

(54) MIM/MIS structure with praseodymium titanate or praseodymium oxide as insulator material

(75) Inventors: Hans-Joachim Mussig, Dresden (DE); Gunther Lippert, Frankfurt (Oder) (DE); Christian Wenger, Berlin (DE)

Correspondence Address: WARE FRESSOLA VAN DER SLUYS &;ADOLPHSON, LLP, BRADFORD GREEN, BUILDING 5, 755 MAIN STREET, P O BOX 224, MONROE, CT, 06468, US

(73) Assignees: IHP GmbH - Innovations for High Performance; Microelectronics/Institut fur Innovative Mikroelektronik

(21) Appl. No.: 11/454,145

(22) Filed: Jun. 14, 2006

(30) Foreign Application Priority Data
Jun. 17, 2005 (DE) 10 2005 028 901.0
Oct. 21, 2005 (DE) 10 2005 051 573.8

(51) Int. Cl. H01L 21/8234; H01L 29/76

(52) U.S. Cl. 438/197; 257/288

(57) ABSTRACT

Disclosed is an electronic device with a layer succession of the metal-insulator-metal (MIM) or metal-insulator-semiconductor (MIS) kind. The insulator layer contains or consists of praseodymium titanate. A metal layer or both metal layers contain titanium nitride (TiN), tantalum nitride (TaN) or ruthenium oxide (RuO₂) or consist of one of those materials. MIM capacitors for mixed signal and HF applications comprising titanium nitride electrodes and an SiO₂/Pr₂Ti₂O₇ layer stack as the dielectric exhibit a high capacitance density of 8 fF/μm² at the very low VCC of −40 ppm/V². The guaranteed operating voltage extrapolated to 10 years is 6 V.

### CROSS REFERENCE TO RELATED APPLICATION

Reference is made to and priority claimed from German application ser. no. 10 2005 028 901.0 filed on Jun. 17, 2005 and German application ser. no. 10 2005 051 573.8 filed Oct. 21, 2005.

### FIELD OF THE INVENTION

The invention concerns an electronic device with a layer succession of the metal-insulator-metal or metal-insulator-semiconductor kind, in which the insulator layer contains praseodymium titanate.

### BACKGROUND OF THE INVENTION

Electronic devices with a layer succession of the kind metal-insulator-metal (MIM) or metal-insulator-semiconductor (MIS) are used for example as memory cells in memory devices such as DRAMs (dynamic random access memory) or as passive components in high-frequency applications.

Functionally, an MIM or an MIS structure, hereinafter also referred to in summarizing form for the sake of brevity as an MIM/MIS structure, forms a capacitor. A metal oxide semiconductor field effect transmitter (MOSFET) involves a layer succession of the metal-insulator-semiconductor kind, wherein the insulator layer performs the function of a gate insulator and the metal layer performs the function of a gate electrode. The semiconductor layer forms a channel for charge carriers between source and drain regions which are also arranged therein. Chip-integrated capacitors which self-evidently are used not only in memories but also in other electronic components are known both in the form of MIM and also MIS structures.

With the constantly progressing miniaturization of electronic devices, the dimensions of the MIM and MIS structures used therein have been so greatly reduced that the use of the insulator materials usually employed, silicon dioxide (SiO₂) and silicon nitride (Si₃N₄), is becoming problematical; because the leakage current rises greatly because of the reduction in the SiO₂ layer thicknesses.

Therefore in past years the search for insulator materials with an elevated dielectric constant (“high-k materials”) has been intensified. Replacement of the conventional materials SiO₂ and Si₃N₄ by alternative dielectric high-k materials is intended primarily to reduce the area of the capacitor. Just recently a number of high-k materials such as Al₂O₃, AlTiOₓ, AlTaOₓ, (HfO₂)₁₋ₓ(Al₂O₃)ₓ, HfO₂, ZrO₂, Y₂O₃, Tr₂O₅, PrTiₓO_{y} and Pr₂O₃ were investigated as potential dielectrics for MIM/MIS capacitors. However, with the exception of Ta₂O₅, all those high-k materials have an excessively high positive square voltage capacitance coefficient (VCC, also identified by α). Therefore multi-layer dielectrics such as SiO₂/HfO₂ and Ta₂O₅/HfO₂/Ta₂O₅ with very good V_{CC} properties are discussed as alternatives. The capacitance density achieved hitherto is a maximum of 6 fF/μm² for that layer stack.

The higher dielectric constant of alternative insulator materials means that it possible to achieve a greater capacitance density with the same area. Particularly promising candidates of such insulator materials are oxides of rare earths, including praseodymium oxide Pr₂O₃, see WO 02/13275.

In terms of the deposit of praseodymium oxide on silicon, it has proven to be advantageous to provide a thin praseodymium silicate intermediate layer which is of a maximum thickness of 5 nm. The praseodymium silicate is a mixed oxide containing silicon, praseodymium and oxygen, see WO 2004/032216 A1.

The use of praseodymium silicide as an electrode material is known, see WO 2004/006315 A2. The disadvantage of praseodymium silicide in relation to MIM/MIS uses is that it is a material which is not simple to integrate into highly developed CMOS process technologies. In particular high temperatures of around 800° C. are required for the deposit of praseodymium silicide, whereby damage can occur at devices already present on the same wafer.

### SUMMARY

The underlying technical object of the present invention is therefore that of providing an electronic device having an improved high-k MIM/MIS structure, which can be easily integrated from the process technology point of view.

In accordance with the invention that object is attained by an electronic device with a layer succession of the metal-insulator-metal or metal-insulator-semiconductor kind, in which the insulator layer of that layer succession contains praseodymium titanate or consists of praseodymium titanate and in which a metal layer of the layer succession or both metal layers of the layer succession contains or contain either titanium nitride TiNₓ, tantalum nitride TaN or ruthenium oxide RuO₂ or a combination of at least two of said materials or consists or consist of one of said materials.

The alternative insulator material praseodymium titanate has the advantage over Pr₂O₃ of enhanced stability in relation to atmospheric influences. Praseodymium titanate is preferably used in the insulator layer in predominantly or completely amorphous form.

In accordance with the invention further a metal layer or both metal layers of the MIM layer succession contains or contain titanium nitride (TiNₓ, hereinafter also referred to for brevity representatively by the embodiment TiN) or tantalum nitride or ruthenium oxide. Alternatively the metal layer or both metal layers consists or consist completely of titanium nitride (TiN), tantalum nitride or ruthenium oxide.

The invention is based on the following realization. Metal electrodes for dual metal gate processes must have suitable work functions, that is to say work functions near the Si conduction band or the Si valence band edge for n- or p-MOSFETs. The change in work function between n⁺-polysilicon and p⁺-polysilicon is between 4.2 eV and 5.2 eV. It is possible to implement both n- and also p-MOSFETs by virtue of the choice of TaN (4.2 eV through 4.9 eV), TiNₓ (4.6 eV through 4.9 eV) or RuO₂ (4.9 eV through 5.2 eV).

In addition the choice of the electrode material is determined by the permissible temperature budget of the process. The specified materials TiNₓ, TaN and RuO₂ are suitable for deposit at low temperatures down to ambient temperature. That facilitates process implementation and avoids damage which is caused by a high thermal budget in terms of process implementation. In contrast to praseodymium silicide the specified materials are therefore easier to handle from the point of view of the process technology. TiN has a metallic conductivity with a specific electrical resistance of 11 μΩcm. The conductivities of TaN and RuO₂ are in the range of between 50 and 250 μΩcm.

Preferred embodiments of the electronic device according to the invention are described hereinafter.

Irrespective of its structural properties praseodymium titanate can be present in the form Pr₂Ti₂O₇ or in an alternative embodiment in the form Pr₂₋ₓTiₓO₃.

In a further embodiment of the electronic device according to the invention the insulator layer contains a praseodymium titanate layer and an SiO₂ layer which adjoins same and which in turn adjoins one of the metal layers or the semiconductor layer. The use of an SiO₂ layer admittedly provides that the capacitance area density, that is to say the ratio of capacitance to area, is slightly reduced, but advantageously the voltage dependency of capacitance can be reduced in that way. An example of such a structure has a first metal electrode, an SiO₂ layer adjoining same, a praseodymium titanate layer adjoining same and a second metal electrode adjoining same.

In a particularly preferred embodiment the layer succession on a silicone substrate has a titanium nitride layer, an SiO₂ layer adjoining the titanium nitride layer, a Pr₂Ti₂O₇ layer adjoining the SiO₂ layer and a gold layer adjoining Pr₂Ti₂O₇ layer. In this embodiment particularly high values in respect of capacitance density were achieved, wherein it is also possible with that structure at the same time to afford a low square voltage capacitance coefficient.

Favorable values of those two parameters can be achieved by a selection of the thicknesses of the SiO₂ layer and the praseodymium titanate layer. Preferably the layer thickness of SiO₂ layer is between 2 and 6 nm. Particularly good values of capacitance density and square voltage capacitance coefficient were achieved with a layer thickness of the SiO₂ layer of 4 nm, in particular in combination with a layer thickness of the Pr₂Ti₂O₇ layer of between 11 and 15 nm, preferably 13 nm.

In a further embodiment the electronic device is in the form of an MIS structure, that is to say it has a layer succession of the metal-insulator-semiconductor kind. In this embodiment the semiconductor layer preferably contains doped silicon or a doped silicon-bearing alloy such as silicon-germanium. The doping corresponds to the usual conductivity doping in electronic devices.

In a further embodiment the metal layer contains a mixture, that is to say besides titanium nitride (TiN) also tantalum nitride (TaN) or ruthenium oxide (RuO₂). The advantages of TaN and RuO₂ correspond to those of the TiN so that the technical object of the invention can also be achieved with a mixture of those materials.

For the production of an MIS structure with a silicon or a silicon-germanium (SiGe) electrode and an SiO₂ layer which adjoins same and which forms a part of the insulator layer, no additional deposit step for the SiO₂ layer is required in the production procedure because the natural SiO₂ layer which is produced with contact with oxygen can be used. Instead of a pure silicon substrate it is also possible to employ a germanium-bearing Si substrate or a carbon-bearing SiGe-alloy.

A preferred configuration of the device according to the invention involves a capacitor structure. Preferably the capacitor structure has a layer succession of the metal-insulator-metal kind, wherein the metal layers form the capacitor electrodes and the insulator layer forms the capacitor dielectric.

In an alternative embodiment the electronic device can also be in the form of a MOSFET which includes a layer succession of the metal-insulator-semiconductor kind, wherein the insulator layer performs the function of a gate insulator and the metal layer performs the function of a gate electrode.

### BRIEF DESCRIPTION OF THE DRAWINGS

Further embodiments by way of example are described hereinafter with reference to the Figures in which:

FIG. 1 shows a portion of a first embodiment of the electronic device of the invention in the form of an MIM capacitor structure,

FIG. 2 shows a portion of a second embodiment of the electronic device of the invention in the form of an MIM capacitor structure, and

FIG. 3 is a diagrammatic view of an embodiment in the form of an MOSFET,

FIG. 4 shows the structure of a further embodiment of an MIM capacitor,

FIG. 5 shows the diagram of the square voltage capacitance coefficient a in the case of MIM capacitors with a pure praseodymium titanate and a pure silicon dioxide dielectric at a frequency of 100 kHz,

FIG. 6 shows standardized C(V) curves of layered Pr₂Ti₂O₇/SiO₂ MIM capacitors as shown in FIG. 4 with a 4 nm thick silicon dioxide layer,

FIG. 7 shows the dependency of the capacitance density and the square voltage capacitance coefficient on different Pr₂Ti₂O₇/SiO₂ MIM capacitors as shown in FIG. 4 in which the layer thickness of the SiO₂ layer is 4 nm,

FIG. 8 shows leakage current densities of different MIM capacitors as shown in FIG. 4 with SiO₂ layers of different thicknesses and a thickness for the Pr₂Ti₂O₇ layer of 13 nm, and

FIG. 9 shows mean breakdown voltages of MIM capacitors with pure praseodymium titanate and with a Pr₂Ti₂O₇/SiO₂ layer structure of the dielectric.

### DETAILED DESCRIPTION

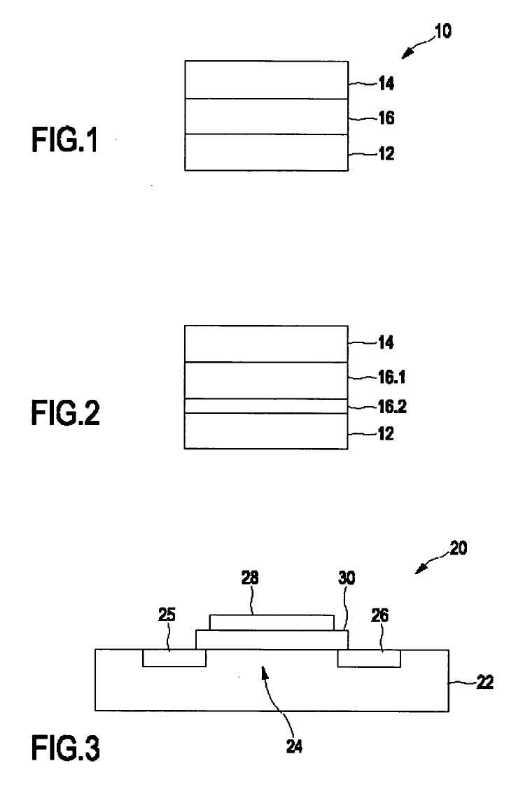

FIG. 1 shows the layer succession of an embodiment of an electronic device in the form of an MIM capacitor structure 10. The MIM structure 10 includes a first capacitor electrode 12 which comprises titanium nitride (TiN), a second capacitor electrode 14 which is also made from titanium nitride TiN and a capacitor dielectric 16 between the first and second capacitor electrodes, which is made from praseodymium titanate. Such a device can be used for example as a memory capacitor in a memory device.

In alternative embodiments the MIM structure 10 can contain either two capacitor electrodes of identical materials or of different materials. Instead of titanium nitride (TiN) the first capacitor electrode can also be made from tantalum nitride (TaN) or ruthenium oxide (RuO₂). The same applies for the second capacitor electrode. The choice of the material is determined by the following points of view:

FIG. 2 shows an alternative embodiment of an electronic device which, with a structure which is otherwise unchanged in relation to FIG. 1, comprises a capacitor dielectric with a layer structure consisting of a praseodymium titanate layer 16.1 and an additional thin SiO₂ layer 16.2.

FIG. 3 shows an embodiment of an MOSFET 20 according to the invention. The MOSFET includes an n-doped silicon substrate 22 in which a channel region 24 is formed. A p-doped source region 25 and a p-doped drain region 26 are provided in the silicon substrate 22. A gate electrode 28 of titanium nitride is disposed over the channel region 24. A gate electrode 28 of praseodymium oxide or praseodymium titanate is arranged between the gate electrode 28 and the channel region 24. The metal-insulator-semiconductor layer succession is therefore formed in the present embodiment by the gate electrode 28, the praseodymium oxide or praseodymium titanate dielectric 30 and the silicon substrate 22. Admittedly in the preferred embodiment the semiconductor substrate is n-doped and the source region 25 and the drain region 26 are each p-doped, but the dopings can also be reversed. In that case the semiconductor substrate would then be p-doped and the source region 25 and the drain region 26 would each be n-doped.

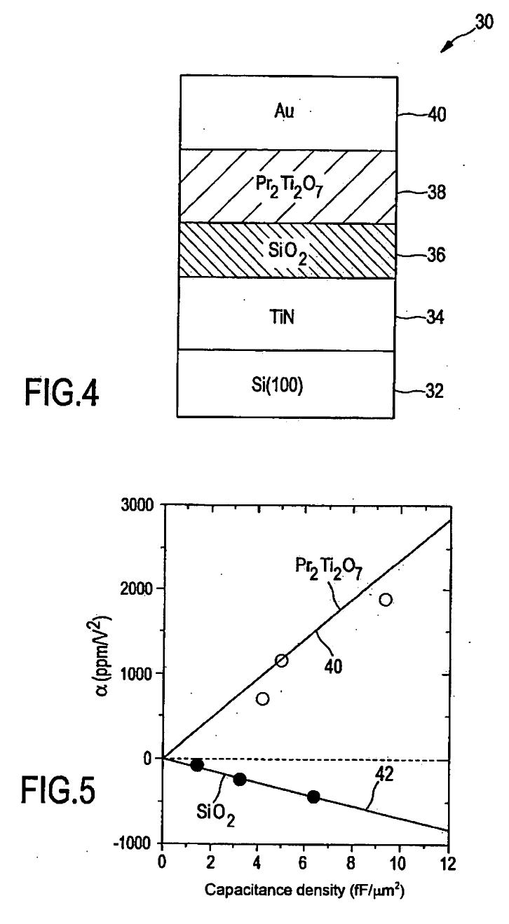

FIG. 4 shows the structure of a further embodiment of an MIM capacitor 30 on a silicon substrate 32 with a crystal orientation (100). Instead of the silicon substrate 32 it is also possible to use a substrate with a silicon-germanium surface layer or an SOI substrate (silicon-on-insulator).

A sputtered TiN layer 34 is used as the lower electrode. An SiO₂ layer 36 is formed thereon by gaseous phase deposition. A dielectric Pr₂Ti₂O₇ layer 38 is deposited by vapor deposition of a Pr₂O₃/TiO₂ mixture. Vapor-deposited Au layers are used as the upper electrode.

In series of tests, various MIM capacitors of that structure with different thicknesses of SiO₂ layers and dielectric Pr₂Ti₂O₇ layers were investigated. Some results of the investigation are set out hereinafter.

FIG. 5 shows a diagram of the square voltage capacitance coefficient α (hereinafter also referred to as VCC) in the units ppm/V² for MIM capacitors with a pure praseodymium titanate and a pure silicon dioxide dielectric at a frequency of 100 kHz in dependence on the capacitance density, plotted in fF/μm². Measurement values for capacitors with praseodymium titanate (Pr₂Ti₂O₇) are represented by open circles and approximated by a straight line 40. Measurement values for capacitors with silicon dioxide are represented by solid circles and approximated by a straight line 42.

The illustrated configuration reflects the fact that C(V) curves of MIM capacitors with pure SiO₂ are of a negative parabolic configuration while MIM capacitors with Pr₂Ti₂O₇ as the dielectric exhibit positive voltage capacitance coefficients (VCC). A constant coefficient can therefore be achieved by a combination of the two dielectrics in a layered MIM structure. The low k value of SiO₂ means that the resulting capacitance is reduced. Therefore the SiO₂ layer should be kept as thin as possible.

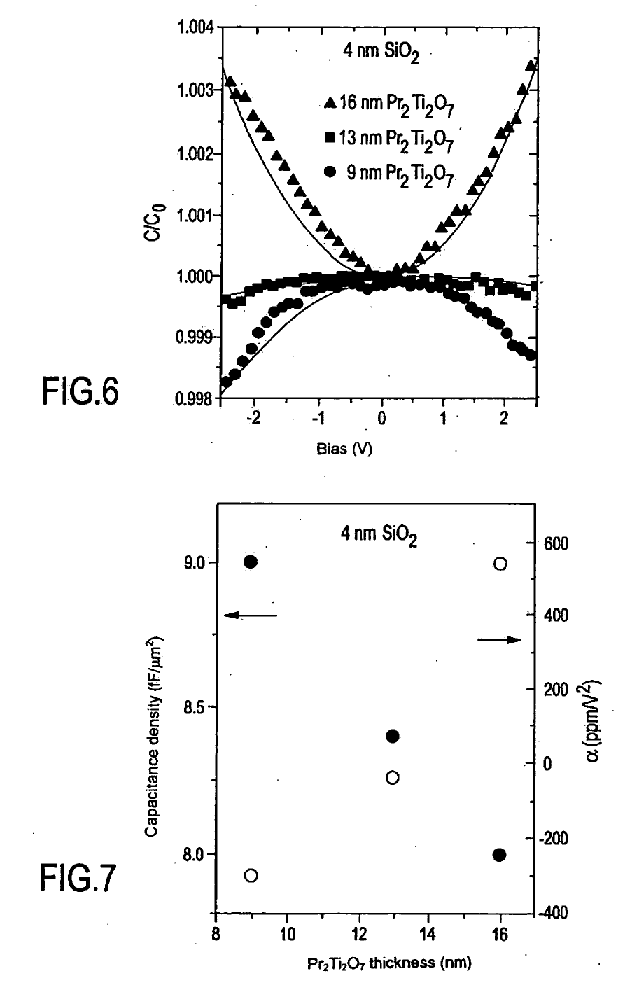

FIG. 6 shows standardized C(V) curves of layered Pr₂Ti₂O₇/SiO₂ MIM capacitors with a 4 nm thick silicon dioxide layer and different thicknesses of Pr₂Ti₂O₇ layers. The measurement results of three samples with 9 nm (circles), 13 nm (squares) and 16 nm (triangles) thick Pr₂Ti₂O₇ layers are shown. All measurement curves exhibit a substantially parabolic C(V) dependency, but VCC clearly changes in sign when the Pr₂Ti₂O₇ thickness is reduced.

FIG. 7 shows the dependencies of capacitance density and square voltage capacitance coefficient ax on the layer thickness of the Pr₂Ti₂O₇ layer in MIM capacitors with a structure as shown in FIG. 4, in which the thickness of the SiO₂ layer is 4 nm. The solid circles show experimentally ascertained values of the capacitance density in fF/μm² and the open circles show experimentally ascertained values of the square voltage capacitance coefficient α (also referred to herein as VCC) in ppm/V². The best result is achieved with a density of the Pr₂Ti₂O₇ layer 38 of 13 nm, more specifically with a capacitance density of 8 fF/μm² at a VCC of −40 ppm/V². Those values satisfy the requirements of the current ITRS.

Upon an increase in the thickness of the SiO₂ layer 36 to 8 nm the sign of the voltage capacitance coefficient remains negative. The best VCC value achieved in a series of samples with identical Pr₂Ti₂O₇ layer thicknesses as in the series in FIG. 7 is −100 ppm/V² with a capacitance density of 3.2 fF/μm². If the thickness of the Pr₂Ti₂O₇ layer 38 is established at 10 nm, the change in the SiO₂ thickness does not lead to any suitable capacitance and linearity values.

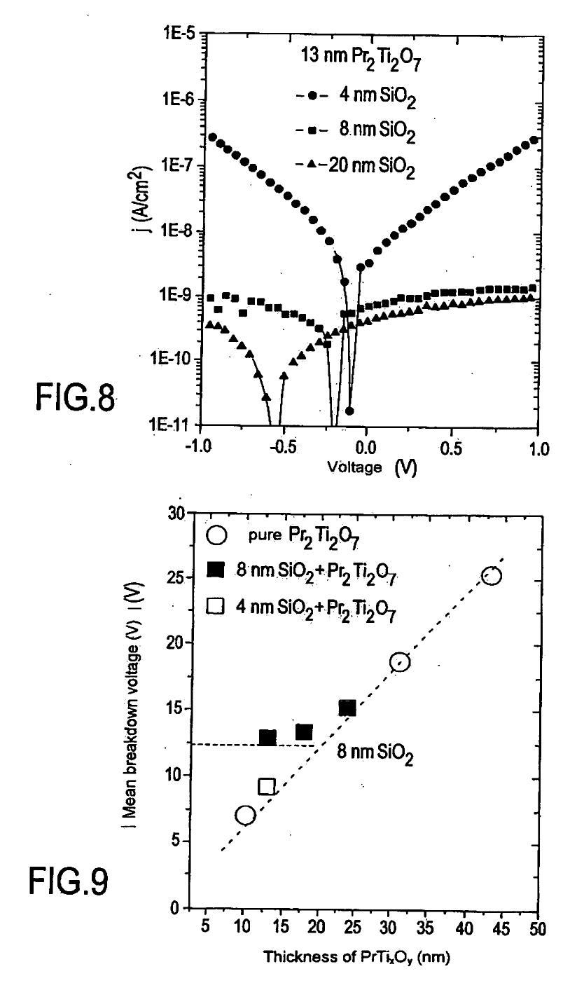

The SiO₂ layer also influence the leakage current properties as well as the breakdown voltage. FIG. 8 shows leakage current densities of various MIM capacitors with different thicknesses of the SiO₂ layer 36, with a thickness for the Pr₂Ti₂O₇ layer 38 of 13 nm. Here too samples were investigated, the structure of which corresponds to that shown in FIG. 4. The leakage current density J is shown in A/cm² as a function of the voltage. Circles characterize measurement values for a sample with 4 nm SiO₂, squares identify measurement values for a sample with 6 nm SiO₂ and triangles identify those for a sample with 20 nm SiO₂. It will be appreciated that the leakage current density decreases with increasing thickness of the SiO₂ layer 36. However there is an asymmetrical configuration in respect of the leakage characteristic. That asymmetry can be determined by the asymmetrical energy band diagram of the SiO₂/Pr₂Ti₂O₇ layer structure.

FIG. 9 shows mean breakdown voltages of MIM capacitors with pure praseodymium titanate and with a Pr₂Ti₂O₇/SiO₂ layer structure as shown in FIG. 4. The mean breakdown voltage is plotted in V as a function of the thickness of the praseodymium titanate layer in nm. The breakdown voltages were taken from I(V) characteristic curves. The breakdown field strength of pure Pr₂Ti₂O₇ ascertained by linear adaptation is 6.5 MV/cm. The breakdown voltage of layered SiO₂/Pr₂Ti₂O₇ MIM capacitors is influenced by the higher dielectric breakdown strength of each layer. The breakdown voltages of layered MIM capacitors with 8 nm SiO₂ and thin Pr₂Ti₂O₇ are determined by the high breakdown strength of the SiO₂.

The operating voltage extrapolated to 10 years is 6 V in the case of MIM capacitors with 8 nm SiO₂ and 24 nm Pr₂Ti₂O₇ and 1 V in the case of capacitors with 4 nm SiO₂ and 13 nm Pr₂Ti₂O₇.

As a result layered high-performance SiO₂/Pr₂Ti₂O₇ MIM capacitors exhibit excellent electrical properties such as high capacitance densities, low voltage capacitance coefficients, high breakdown field strengths and a high level of reliability for the device.

1. An electronic device comprising a plurality of layers of respective materials so as to form a layer succession of materials, wherein the layer succession is metal-insulator-metal or metal-insulator-semiconductor, in which the insulator layer of the layer succession contains praseodymium titanate or consists of praseodymium titanate and in which a metal layer of the layer succession or both metal layers of the layer succession contain either titanium nitride TiNₓ, tantalum nitride TaN or ruthenium oxide RuO₂ or a combination of at least two of said materials or consists or consist of one of said materials.

2. An electronic device as set forth in claim 1 wherein praseodymium titanate is present in the form Pr₂Ti₂O₇.

3. An electronic device as set forth in claim 1 wherein praseodymium titanate is present in the form Pr₂₋ₓTiₓO₃.

4. An electronic device as set forth in claim 1 wherein the praseodymium titanate is present predominantly or completely in amorphous form.

5. An electronic device as set forth in claim 1 wherein the insulator layer contains a praseodymium titanate layer and an SiO₂ layer adjoining same or consists of a praseodymium titanate layer and an SiO₂ layer adjoining same, and wherein the SiO₂ layer adjoins either one of the metal layers of the layer succession or the semiconductor layer of the layer succession.

6. An electronic device as set forth in claim 5 wherein the layer succession on a silicon substrate has a titanium nitride layer, an SiO₂ layer adjoining the titanium nitride layer, a Pr₂Ti₂O₇ layer adjoining the SiO₂ layer and a gold layer adjoining the Pr₂Ti₂O₇ layer.

7. An electronic device set forth in claim 6 wherein the layer thickness of the SiO₂ layer is between 2 and 6 nm.

8. An electronic device set forth in claim 7 wherein the layer thickness of the SiO₂ layer is 4 nm.

9. An electronic device as set forth in claim 7 wherein the layer thickness of the Pr₂Ti₂O₇ layer is between 11 and 15 nm.

10. An electronic device as set forth in claim 9 wherein the layer thickness of the Pr₂Ti₂O₇ layer is 13 nm.

11. An electronic device as set forth in claim 1, wherein the metal layer besides titanium nitride TiN also contains tantalum nitride TaN or ruthenium oxide RuO₂.

12. An electronic device as set forth in claim 1, wherein the semiconductor layer contains doped silicon or a doped silicon-bearing alloy.

13. An electronic device as set forth in claim 1, wherein the electronic device is in the form of an MOSFET having a layer succession of metal-insulator-semiconductor, wherein the insulator layer performs the function of a gate insulator and the metal layer performs the function of a gate electrode.

14. An electronic device as set forth in claim 1, wherein the electronic device is in the form of a capacitor having a layer succession of metal-insulator-metal, wherein the metal layers form the capacitor electrodes and the insulator layer forms the capacitor dielectric.
